(19) United States
(12) Patent Application Publication
(10) Pub. No.: US 2024/0341029 A1
(43) Pub. Date: Oct. 10, 2024

(54) MULTILAYER PACKAGE-ON-PACKAGE ASSEMBLY AND METHOD FOR PACKAGING MULTILAYER ASSEMBLY

(71) Applicant: SPREADTRUM COMMUNICATIONS (SHANGHAI) CO., LTD., Shanghai (CN)

(72) Inventors: Li YAO, Shanghai (CN); Fatian FU, Shanghai (CN); Haiyan MA, Shanghai (CN)

(21) Appl. No.: 18/681,388

(22) PCT Filed: Aug. 5, 2022
(86) PCT No.: PCT/CN2022/110608

§ 371 Date: Feb. 5, 2024

(30) Foreign Application Priority Data
Aug. 6, 2021 (CN) 202110901762.9

(51) Int. Cl. H05K 1/02; H05K 1/14; H05K 3/36; H05K 9/00

(52) U.S. Cl. CPC H05K 1/023; H05K 1/144; H05K 3/368; H05K 9/0032; H05K 2201/10371; H05K 2201/10378; H05K 2203/1377

(57) ABSTRACT

A multilayer package-on-package (PoP) assembly and a method for packaging a multilayer assembly are provided. The multilayer PoP assembly includes at least two circuit boards. An interposer is disposed between two adjacent circuit boards of the at least two circuit boards. A shield is disposed on an upper contact surface and/or a lower contact surface of the interposer in contact with the at least two circuit boards. Electrical elements on a corresponding contact surface are all surrounded by the shield. A height of the shield is not less than a height of each of the electrical elements.

### CROSS-REFERENCE TO RELATED APPLICATION(S)

This application is a National Stage of International Application No. PCT/CN2022/110608, field on Aug. 5, 2022, which claims priority to Chinese Patent Application No. 202110901762.9, filed on Aug. 6, 2021, both of which are incorporated by reference herein.

### TECHNICAL FIELD

This disclosure relates to the field of packaging technology, and in particular to a multilayer package-on-package assembly and a method for packaging a multilayer assembly.

### BACKGROUND

During conventional single-layer system-in-package (SiP)/module-in-package (MiP), external electromagnetic interference (EMI) coating processes or metal can processes are generally adopted to shield electromagnetic interference.

### SUMMARY

In a first aspect, a multilayer PoP assembly is provided in the present disclosure. The multilayer PoP assembly includes at least two circuit boards. An interposer is disposed between two adjacent circuit boards of the at least two circuit boards. A shield is disposed on an upper contact surface and/or a lower contact surface of the interposer in contact with the at least two circuit boards. Electrical elements on a corresponding contact surface are all surrounded by the shield. A height of the shield is not less than a height of each of the electrical elements.

In a second aspect, a method for packaging a multilayer assembly is provided in the present disclosure. The multilayer assembly includes at least two circuit boards. The method includes: disposing a shield on an upper contact surface and/or a lower contact surface of an interposer, wherein electrical elements on a corresponding contact surface are all surrounded by the shield, and a height of the shield is not less than a height of each of the electrical elements; disposing an interposer between any two adjacent circuit boards of the at least two circuit boards; and forming, based on an EMI coating process, a shield coating on an outer surface of the multilayer assembly and on an outer surface the interposer.

### BRIEF DESCRIPTION OF THE DRAWINGS

FIG. 1 is a schematic cross-sectional side view of a multilayer package-on-package (PoP) assembly according to embodiments of the present disclosure.

FIG. 2 is a schematic top view of a shield in the multilayer PoP assembly according to embodiments of the present disclosure.

FIG. 3 is a flowchart of a method for packaging a multilayer assembly according to embodiments of the present disclosure.

### DETAILED DESCRIPTION

The following will further illustrate the present disclosure by means of embodiments, but the present disclosure is not limited to the scope of the embodiments.

For system-in-package (SiP)/module-in-package (MiP) of a multilayer stacked structure, a basic method of an electromagnetic interference (EMI) coating process or a metal can process is still adopted, resulting in following problems.

For the EMI coating process, due to a conductive property of a coating material, in order to prevent electrical failure, the coating material cannot be used in a region where different substrates are bonded, resulting in ineffective shielding of the region where different substrates are bonded.

For the metal can process, since the metal can process adopts an entire coverage manner, with the increase of stacked structures, the size of an entire package assembly will become larger due to a shielding cover.

The technical problem to be solved by the present disclosure is to overcome the above defects in the related art, and the present disclosure provides a multilayer package-on-package (PoP) assembly and a method for packaging a multilayer assembly.

The present disclosure solves the above technical problem by means of following technical solutions.

As illustrated in FIG. 1, a PoP assembly includes at least two circuit boards 1. An interposer 2 is disposed between two adjacent circuit boards 1 of the at least two circuit boards. A shield 3 is disposed on an upper contact surface and/or a lower contact surface of the interposer 2 in contact with the at least two circuit boards 1. It may be noted that in actual applications, the shield 3 is disposed on a required contact surface according to actual needs.

Electrical elements 4 on a corresponding contact surface are all surrounded by the shield 3. A height of the shield 3 is not less than a height of each of the electrical elements 4. In other embodiments, in order to make the size of the entire package assembly more compact, the height of the shield 3 is equal to the maximum height of the electrical element 4. The electrical elements 4 each may be a basic circuit structure such as a copper pad, a solder joint, or a solder ball 7. In other words, for all electrical elements 4, a circuit structure of each electrical element 4 may be a copper pad; for all electrical elements 4, a circuit structure of each electrical element 4 may be a solder pad; for all electrical elements 4, a circuit structure of each electrical element 4 may be a solder ball; for all electrical elements 4, a circuit structure of each of some electrical elements 4 may be a copper pad, a circuit structure of each of the other electrical elements 4 may be a solder pad; for all electrical elements 4, a circuit structure of each of some electrical elements 4 may be a copper pad, a circuit structure of each of the other electrical elements 4 may be a solder ball; for all electrical elements 4, a circuit structure of each of some electrical elements 4 may be a solder pad, a circuit structure of each of the other electrical elements 4 may be a solder ball; or for all electrical elements 4, a circuit structure of each of some electrical elements 4 may be a copper pad, a circuit structure of each of other electrical elements 4 may be a solder pad, and a circuit structure of each of the rest of electrical elements may be a solder ball.

In addition, referring to FIG. 1, each circuit board 1 is provided with an electronic element 5. The package assembly includes a shield coating 6, formed based on an EMI coating process, on an outer surface of the package assembly. The shield coating 6 and the shield 3 form a shield assembly of the multilayer PoP assembly.

It may be noted that the electrical elements 4 on the corresponding contact surface are all surrounded by the shield 3, the interposer 2 is disposed between two adjacent circuit boards 1, and the shield coating 6 is then formed on the outer surface of the package assembly based on the EMI coating process. The entire multilayer assembly is just wrapped by the shield coating 6. In addition, the shield coating 6 is just physically connected to the shield 3 disposed in the gap between the stacked substrates. Therefore, a complete shielding layer is formed.

The shield 3 is connected to the interposer 2 by pasting or soldering. It may be noted that in this case, it is mainly considered that, since a relatively large soldering gap exists between the substrates, such as ball grid array (BGA) soldering, the shield 3 with a certain thickness needs to be prepared in some situations, so that the height of the shield 3 can be matched with the height of the solder ball 7.

Alternatively, in response to the height of the shield 3 is less than a preset value, the shield 3 is formed on the interposer 2 by electroplating.

It may be noted that in this case, it is mainly considered that, if the height of the electrical element 4 on the corresponding contact surface is relatively low, when the interposer 2 is manufactured, the shield 3 may be directly formed by electroplating on the surface of the interposer 2, which is more convenient.

In this embodiment, the material of the shield 3 includes a conductive metal. In other embodiments, the material of the shield 3 is copper.

In this embodiment, a shape of the shield 3 includes any one of a hollow circle, a hollow square, and a hollow rectangle.

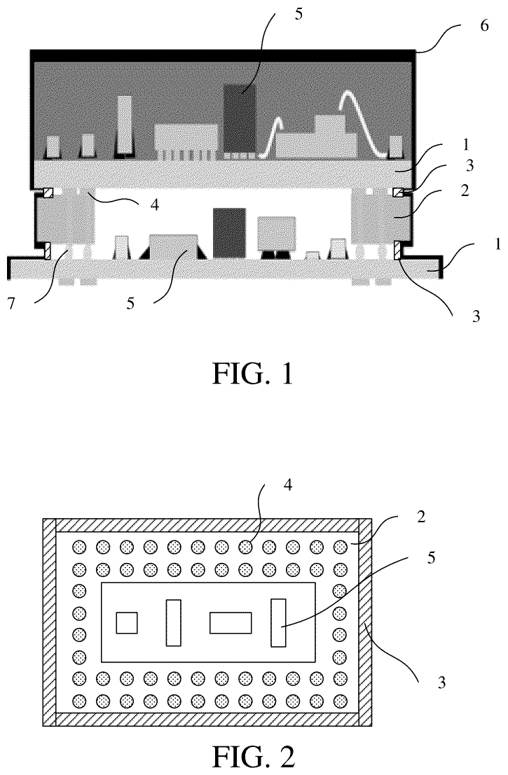

It may be noted that the shape of the shield 3 is mainly determined according to shapes of the at least two circuit boards 1 and distribution of the electrical elements 4 on the circuit board 1 and the interposer 2. Generally, considering that the circuit board 1 is mostly rectangular, the shield 3 is also rectangular. Reference can be made to FIG. 2, which illustrates a top view of a shield.

In this embodiment, in combination with the EMI coating process, the shield is disposed on the interposer of the multilayer assembly. Therefore, the volume of the entire package assembly is ensured to be small, and poor EMI protection due to the gap caused by the stacked substrates is avoided.

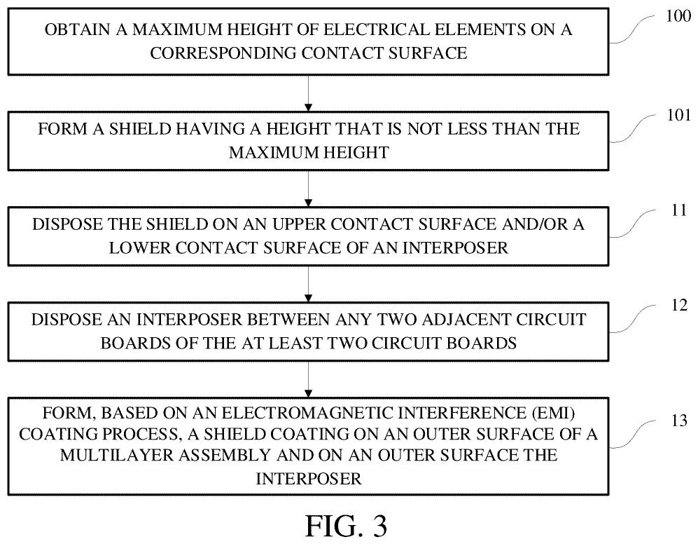

A method for packaging a multilayer assembly is provided. The multilayer assembly includes at least two circuit boards. As illustrated in FIG. 3, the method includes the following.

11, dispose a shield on an upper contact surface and/or a lower contact surface of an interposer, where electrical elements on a corresponding contact surface are all surrounded by the shield, and a height of the shield is not less than a height of each of the electrical elements; where each of the electrical elements may be a basic circuit structure such as a copper pad, a solder joint, a solder ball, or the like.

It may be noted that in actual applications, the shield is disposed on a required contact surface according to actual needs.

12, dispose an interposer between any two adjacent circuit boards of the at least two circuit boards.

13, form, based on an EMI coating process, a shield coating on an outer surface of the multilayer assembly and on an outer surface the interposer.

In this embodiment, prior to 11, the method further include: 100, obtain a maximum height of the electrical elements on the corresponding contact surface; 101, form the shield having the height that is not less than the maximum height.

Further, 11 specifically includes: paste or solder the shield to the corresponding contact surface.

It may be noted that in this case, it is mainly considered that, since a relatively large soldering gap exists between the substrates, such as BGA soldering, the shield with a certain thickness needs to be prepared in some situations, so that the height of the shield can be matched with the height of the solder ball.

In addition, another implementation of 11 is provided in this embodiment, and specifically includes: obtain a maximum height of the electrical elements on the corresponding contact surface, and in response to the maximum height being less than a preset value, form the shield on the interposer by electroplating.

It may be noted that in this case, it is mainly considered that, if the height of the electrical element on the corresponding contact surface is relatively low, when the interposer is manufactured, the shield may be directly formed by electroplating on the surface of the interposer, which is more convenient.

In this embodiment, in combination with the EMI coating process, the shield is disposed on the interposer of the multilayer assembly. Therefore, the volume of the entire package assembly is ensured to be small, and poor EMI protection due to the gap caused by the stacked substrates is avoided.

In a first aspect, a multilayer PoP assembly is provided in the present disclosure. The multilayer PoP assembly includes at least two circuit boards. An interposer is disposed between two adjacent circuit boards of the at least two circuit boards. A shield is disposed on an upper contact surface and/or a lower contact surface of the interposer in contact with the at least two circuit boards. Electrical elements on a corresponding contact surface are all surrounded by the shield. A height of the shield is not less than a height of each of the electrical elements.

In embodiments of the present disclosure, the multilayer PoP assembly includes a shield coating, formed based on an EMI coating process, on an outer surface of the multilayer PoP assembly. The shield coating and the shield form a shield assembly of the multilayer PoP assembly.

In embodiments of the present disclosure, the shield is connected to the interposer by pasting or soldering; or in response to the height of the shield being less than a preset value, the shield is formed on the interposer by electroplating.

In embodiments of the present disclosure, a material of the shield includes a conductive metal.

In embodiments of the present disclosure, a material of the shield includes copper.

In embodiments of the present disclosure, a shape of the shield includes any one of a hollow circle, a hollow square, and a hollow rectangle.

In a second aspect, a method for packaging a multilayer assembly is provided in the present disclosure. The multilayer assembly includes at least two circuit boards. The method includes: disposing a shield on an upper contact surface and/or a lower contact surface of an interposer, wherein electrical elements on a corresponding contact surface are all surrounded by the shield, and a height of the shield is not less than a height of each of the electrical elements; disposing an interposer between any two adjacent circuit boards of the at least two circuit boards; and forming, based on an EMI coating process, a shield coating on an outer surface of the multilayer assembly and on an outer surface the interposer.

In embodiments of the present disclosure, prior to disposing the shield on the upper contact surface and/or the lower contact surface of the interposer, the method further includes: obtaining a maximum height of the electrical elements on the corresponding contact surface; and forming the shield having the height that is not less than the maximum height.

In embodiments of the present disclosure, disposing the shield on the upper contact surface and/or the lower contact surface of the interposer specifically includes: pasting or soldering the shield to the corresponding contact surface.

In embodiments of the present disclosure, disposing the shield on the upper contact surface and/or the lower contact surface of the interposer specifically includes: obtaining a maximum height of the electrical elements on the corresponding contact surface; and forming the shield on the interposer by electroplating, in response to the maximum height being less than a preset value.

The present disclosure has positive and progressive effects as follows. In combination with the EMI coating process, the shield is disposed on the interposer of the multilayer assembly. Therefore, the volume of the entire package assembly is ensured to be small, and poor EMI protection due to a gap caused by stacked substrates is avoided.

Although specific implementations of the present disclosure have been described above, it may be understood by those skilled in the art that this is by way of example only and that the scope of the present disclosure is defined by the appended claims. Those skilled in the art can make various changes or modifications to these implementations without departing from the principle and essence of the present disclosure, and these changes and modifications shall belong to the scope of protection of the present disclosure.

1. A multilayer package-on-package (PoP) assembly, comprising at least two circuit boards, wherein an interposer is disposed between two adjacent circuit boards of the at least two circuit boards, and a shield is disposed on an upper contact surface and/or a lower contact surface of the interposer in contact with the at least two circuit boards; and
electrical elements on a corresponding contact surface are all surrounded by the shield, and a height of the shield is not less than a height of each of the electrical elements.

2. The multilayer PoP assembly of claim 1, further comprising a shield coating, formed based on an electromagnetic interference (EMI) coating process, on an outer surface of the multilayer PoP assembly; wherein
the shield coating and the shield form a shield assembly of the multilayer PoP assembly.

3. The multilayer PoP assembly of claim 1, wherein the shield is connected to the interposer by pasting or soldering; or
in response to the height of the shield being less than a preset value, the shield is formed on the interposer by electroplating.

4. The multilayer PoP assembly of claim 1, wherein a material of the shield comprises a conductive metal.

5. The multilayer PoP assembly of claim 3, wherein a material of the shield comprises copper.

6. The multilayer PoP assembly of claim 1, wherein a shape of the shield comprises any one of a hollow circle, a hollow square, and a hollow rectangle.

7. The multilayer PoP assembly of claim 1, wherein the height of the shield equals to a height of an electrical element having a maximum height among the electrical elements.

8. The multilayer PoP assembly of claim 1, wherein a circuit structure of each of the electrical elements is a copper pad, a solder joint, or a solder ball.

9. The multilayer PoP assembly of claim 2, wherein the shield coating is physically connected to the shield.

10. The multilayer PoP assembly of claim 1, wherein a shape of the shield is determined according to shapes of the at least two circuit boards and distribution of the electrical elements on the circuit board and the interposer.

11. A method for packaging a multilayer assembly, wherein the multilayer assembly comprises at least two circuit boards, and the method comprises:
disposing a shield on an upper contact surface and/or a lower contact surface of an interposer, wherein electrical elements on a corresponding contact surface are all surrounded by the shield, and a height of the shield is not less than a height of each of the electrical elements;
disposing an interposer between any two adjacent circuit boards of the at least two circuit boards; and
forming, based on an electromagnetic interference (EMI) coating process, a shield coating on an outer surface of the multilayer assembly and on an outer surface the interposer.

12. The method for packaging the multilayer assembly of claim 11, wherein prior to disposing the shield on the upper contact surface and/or the lower contact surface of the interposer, the method further comprises:
obtaining a maximum height of the electrical elements on the corresponding contact surface; and
forming the shield having the height that is not less than the maximum height.

13. The method for packaging the multilayer assembly of claim 12, wherein disposing the shield on the upper contact surface and/or the lower contact surface of the interposer comprises:
pasting or soldering the shield to the corresponding contact surface.

14. The method for packaging the multilayer assembly of claim 11, wherein disposing the shield on the upper contact surface and/or the lower contact surface of the interposer comprises:
obtaining a maximum height of the electrical elements on the corresponding contact surface; and
forming the shield on the interposer by electroplating, in response to the maximum height being less than a preset value.

15. The method for packaging the multilayer assembly of claim 11, wherein a material of the shield comprises a conductive metal.

16. The method for packaging the multilayer assembly of claim 11, wherein a shape of the shield comprises any one of a hollow circle, a hollow square, and a hollow rectangle.

17. The method for packaging the multilayer assembly of claim 11, wherein the height of the shield equals to a height of an electrical element having a maximum height among the electrical elements.

18. The method for packaging the multilayer assembly of claim 11, wherein a circuit structure of each of the electrical elements is a copper pad, a solder joint, or a solder ball.

19. The method for packaging the multilayer assembly of claim 11, wherein the shield coating is physically connected to the shield.

20. The method for packaging the multilayer assembly of claim 11, wherein a shape of the shield is determined according to shapes of the at least two circuit boards and distribution of the electrical elements on the circuit board and the interposer.
